(19) United States
(12) Patent Application Publication
(10) Pub. No.: US 2024/0210448 A1
(43) Pub. Date: Jun. 27, 2024

(54) VOLTAGE GRID ANOMALY DETECTION

(71) Applicant: Itron, Inc., Liberty Lake, WA (US)

(72) Inventors: Melvin James Gehrs, Downers Grove, IL (US); David Wu Ganger, Lakewood, CO (US); Timothy James Driscoll, Raleigh, NC (US); Chaitanya Ashok Baone, Fremont, CA (US)

(21) Appl. No.: 18/089,353

(22) Filed: Dec. 27, 2022

(51) Int. Cl. G01R 19/02; G01R 19/165

(52) U.S. Cl. CPC G01R 19/02; G01R 19/16585

(57) ABSTRACT

A method, apparatus, and computer-readable storage medium for detecting voltage anomaly in an electrical grid are provided. An electricity meter may collect voltage data by sampling a voltage waveform of the electrical grid at a preselected sampling rate; based on the voltage data, determine standard voltage waveform statistics of voltage of the electrical grid including statistical metrics; determine a range for the statistical metrics based on the standard voltage waveform statistics; at a preselected interval, calculate a statistical value of the statistical metrics of a present voltage waveform sampled at the preselected sampling rate for a preselected interval of the present voltage waveform; and in response to determining that the statistical value is outside of the range: capturing a predetermined number of cycles of voltage waveforms around the present voltage waveform, and sending an alarm to a remote computing device associated with the electrical grid.

### TECHNICAL FIELD

The present disclosure generally relates to the field of electrical grid voltage monitoring, and more specifically to methods, devices, and systems for detecting anomaly in the electrical grid based on the monitored voltage.

### BACKGROUND

An electrical grid may be impacted by hurricanes, earthquakes, and/or accidents resulting in hazards such as tree contact, arcing, wire down, capacitor bank malfunction, tap changer, recloser malfunction, and the like. As a result, voltage sags and/or swells, and even small interruptions in the 60 Hz waveform of the voltage signal, can have a profound effect on customers. Such interruptions, or anomalies, in the voltage waveforms can cause from minor inconveniences, such as blinking clocks and rebooting computers, to major issues, such as shutting down commercial and industrial processes, losing production time, wasting supplies, and even damaging equipment. Unlike the current, which is a local customer effect, anomalies in the voltage can be geographically diverse and represent utility equipment malfunctions in a region of the grid or even a system-wide transmission/generation malfunction such as the impact of a hurricane on the overall grid or the sudden loss of a generating station.

### BRIEF DESCRIPTION OF THE DRAWINGS

The detailed description is set forth with reference to the accompanying figures. In the figures, the left-most digit(s) of a reference number identifies the figure in which the reference number first appears. The use of the same reference numbers in different figures indicates similar or identical items or features.

FIG. 1 illustrates an example power distribution environment in which voltage grid anomaly detection may be utilized.

FIG. 2 illustrates an example block diagram of an electricity meter.

FIG. 3 illustrates a graph depicting a 60 Hz voltage waveform and a crest factor chart for various waveforms with associated parameter values.

FIG. 4 illustrates graphs depicting an abnormal 60 Hz voltage waveform and an abnormal crest factor.

FIG. 5 illustrates skewness graphs with a zero skew, a negative skew, and a positive skew.

FIG. 6 illustrates kurtosis graphs with zero kurtosis, a positive kurtosis, and a negative kurtosis.

FIG. 7 illustrates an example process for detecting a voltage anomaly in the grid.

FIG. 8 illustrates a flow chart representing an example detail process of one of the blocks of FIG. 7.

FIG. 9 illustrates a flow chart representing an example detail process of another block of FIG. 7.

### DETAILED DESCRIPTION

This application describes methods and apparatus for detecting voltage anomaly in an electrical grid. An electricity meter monitors a voltage waveform of the electricity grid, and with statistical analyses of the voltage waveform against a standard or a benchmark data, detects a voltage anomaly.

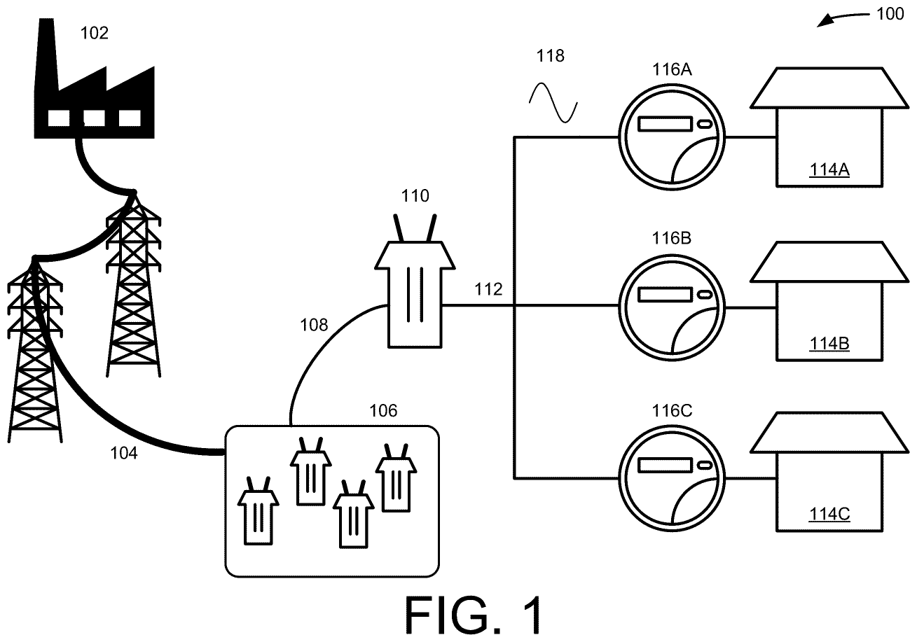

FIG. 1 illustrates an example environment, or grid, 100 in which voltage grid anomaly detection may be utilized. In this example, a power plant 102 generates electricity, which is carried by high voltage lines 104 to a power substation 106. The power substation 106 provides electricity via a feeder 108 to a transformer 110. The feeder 108 is a power line consisting of individual power lines 112 servicing a plurality of premises 114 (three premises, 114A, 114B, and 114C, are shown, though the grid 100 may include any number of premises 114) connected via the transformer 110 and electricity meters 116A, 116B, and 116C providing electricity to associated premises 114A, 114B, and 114C. While the amplitude of the voltage may change in the electrical grid 100, the waveform of the voltage remains the same in the electrical grid 100. For example, while the amplitude of the voltage may change from 115 kV at the high voltage lines 104 to 13.8 kV at the feeder 108, then to 480/240/120 V at the individual power lines 112, the waveform of the voltage remains the same throughout the electrical grid 100, generally as a 60 Hz sine wave 118. Therefore, the voltage waveform of the electrical grid 100 may be monitored at individual electricity meters, such as the electricity meters 116A, 116B, and 116C.

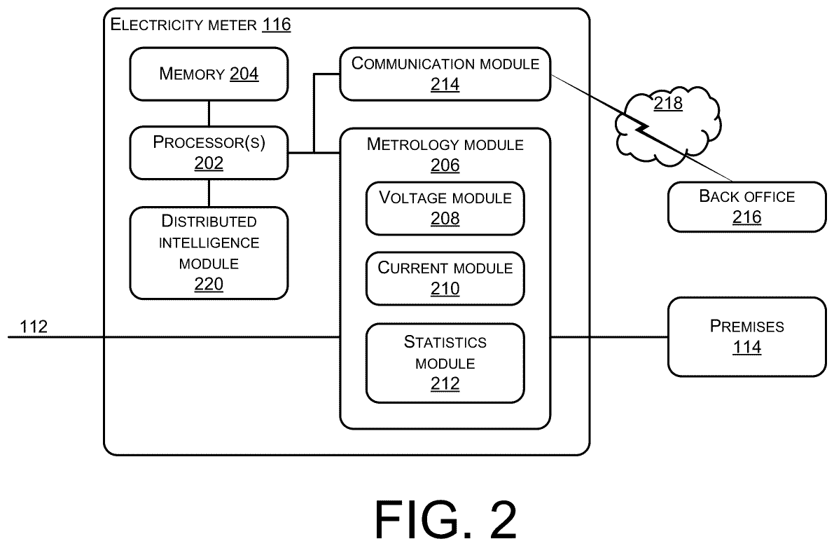

FIG. 2 illustrates an example block diagram of the electricity meter 116. The electricity meter 116 may comprise one or more processors (e.g., processors 202) communicatively coupled to memory 204. The processors 202 may include one or more central processing units (CPUs), graphics processing units (GPUs), both CPUs and GPUs, or other processing units or components known in the art. The processors 202 may execute computer-executable instructions stored in the memory 204 to perform functions or operations with one or more of components, or modules, communicatively coupled to the one or more processors 202. Depending on the exact configuration of the electricity meter 116, the memory 204 may be volatile, such as RAM, non-volatile, such as ROM, flash memory, miniature hard drive, memory card, and the like, or some combination thereof. The memory 204 may store computer-executable instructions that are executable by the processors 202.

The components, or modules, of the electricity meter 116 coupled to the processors 202 and/or the memory 204 may include a metrology module 206. The metrology module 206 may be capable of performing tasks, such as monitoring, measuring, and calculating, associated with various electricity related metrics on the individual power line 112 and the premises 114 connected to the electricity meter 116. For example, the metrology module 206 may include a voltage module 208 and a current module 210. The voltage module 208 may perform voltage related tasks, such as measuring and monitoring amplitude and frequency of the voltage on the individual power line 112, and the current module 210 may perform current related tasks, such as measuring and monitoring amplitude and frequency of the current on the individual power line 112. The metrology module 206 may also include a statistics module 212 for calculating various metrics, such as power consumption, voltage and current variations, and associated statistics, based on measured parameters from the voltage module 208 and the current module 210. “Statistics” and “statistical values” defined herein includes a collection of quantitative data associated with measured parameters from the voltage module 208 and the current module 210 as well as mathematical analysis, interpretation, and presentation of the collected quantitative data. The metrology module 206 may be capable of sampling the voltage and current on the individual power line 112 at a high sampling rate of 4-32 kHz. The electricity meter 116 may additionally include a communication module 214 for communicating with a back office, or a remote computing device in the back office, 216 associated with the electrical grid 100. The communication module 214 may communicate with the back office 216 via a wired or wireless communication network 218, such as the Internet, a cellular network, local area network (LAN), wireless LAN (WLAN), and the like. The communication module 214 may transmit data or information collected by the metrology module 206 to the back office 216 and receive instructions and data from the back office 216. The communication module 214 may communicate with the back office 216 as needed or periodically at a predetermined interval. The electricity meter 116 may additionally comprise a distributed intelligence (DI) module 220 coupled to the processors 202. The DI module 220 may perform functions associated statistics module 212, instead of, along with the processors 202 by running one or more DI agents. The electricity meter 116 is located at the periphery of the electrical grid 100, i.e., at premises of the end consumer of electricity. The electricity meter 116 may also be referred to as an edge computing device, or simply as an edge device 116 based on the DI capability for taking storage and computing resources from a central location, such as the back office 216, and moving those resources to locations where the data is generated, such as at one or more electricity meters 116.

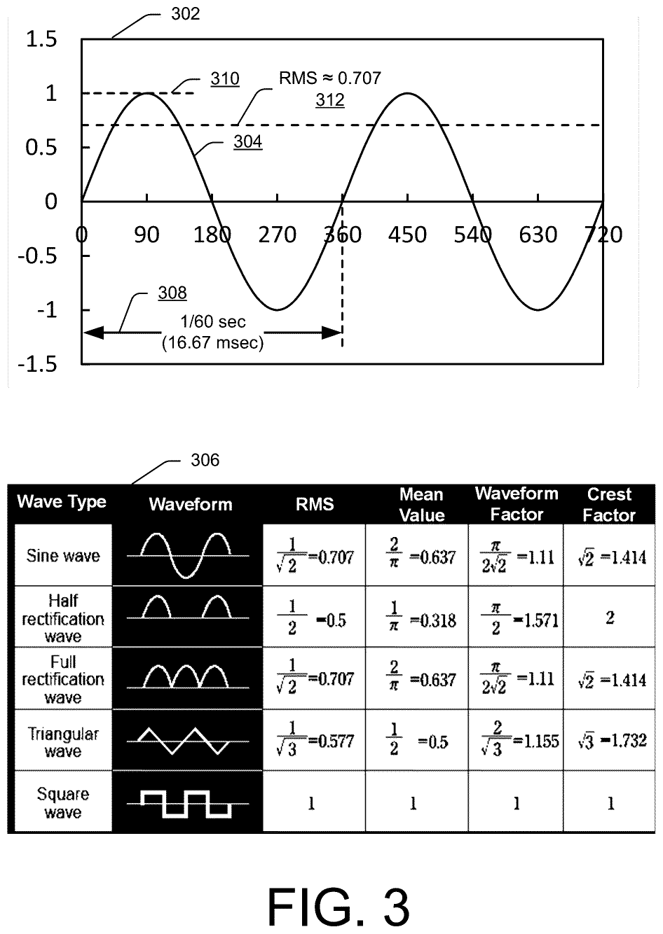

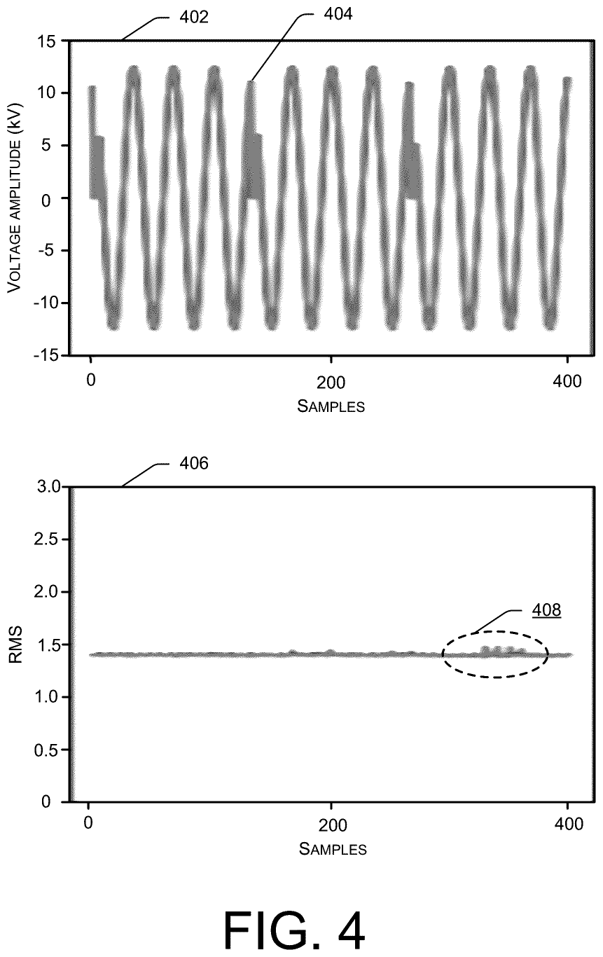

To detect a voltage anomaly in the electrical grid 100, advanced statistical algorithms, such as crest factor, skewness, and kurtosis, may be utilized to trigger waveform capture and potentially recognition of grid and even system wide events. The crest factor is a mathematical algorithm used to measure the shape and symmetry of a waveform, such as the voltage waveform on the individual power line 112 monitored by the electricity meter 116. The crest factor is calculated by dividing the peak voltage by the root-mean-square (RMS) value of the waveform. FIG. 3 illustrates a graph 302 depicting a normal 60 Hz voltage waveform 304 and a crest factor chart 306 for various waveforms with associated parameter values. The normal 60 Hz voltage waveform 304 is a sinusoidal wave, which has a period 308 of 1/60 second (16.67 msec), a relative peak 310 with a value of 1, and an RMS 312 with a value of 1/\sqrt{2} (approximately 0.707). Any deviation from the normal, or expected, parameter values, as shown in the crest factor chart 306, indicates some distortion in the waveform. FIG. 4 illustrates a graph 402 depicting an example abnormal 60 Hz voltage waveform 404 sampled at 2 kHz and a crest factor graph 406 showing values 408 different from the expected value of a value of \sqrt{2} (approximately 1.404). As can be seen in the voltage waveform 404, the peak amplitude varies and there are some secondary peaks not present in a normal 60 Hz voltage waveform, such as the normal 60 Hz voltage waveform 304 shown in FIG. 3. These variations cause deviations from the normal parameter values, such as the RMS values 408 deviating from the expected value of 1.404 as shown in FIG. 4.

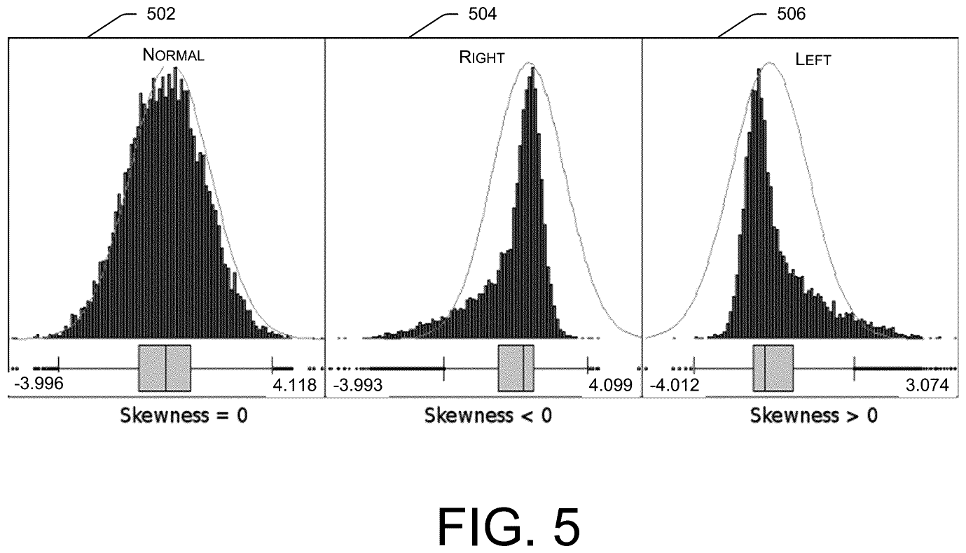

FIG. 5 illustrates skewness graphs with a first graph 502 showing zero skew, a second graph 504 showing right or negative skew, and a third graph 506 showing left or positive skew. The skew of a waveform/distribution is a measure of the asymmetry of the shape of the curve, and may be used to detect abnormal waveforms. A curve is asymmetric if the left and right sides of the distribution around the median are not a mirror image of each other. Mathematically, a zero skew has a perfect mirror image around the median where a negative skew is shifted to the right and a positive skew is shifted to the left. Graph 502 illustrates a symmetric distribution with a skewness=0, which would be the expected shape for a normal 60 Hz voltage waveform, such as the normal 60 Hz voltage waveform 304 shown in FIG. 3. Graph 504 illustrates a right-shifted distribution with a skewness <0. Graph 506 illustrates a left-shifted distribution with a skewness >0. A perfect 60 Hz voltage waveform should have a skewness of zero.

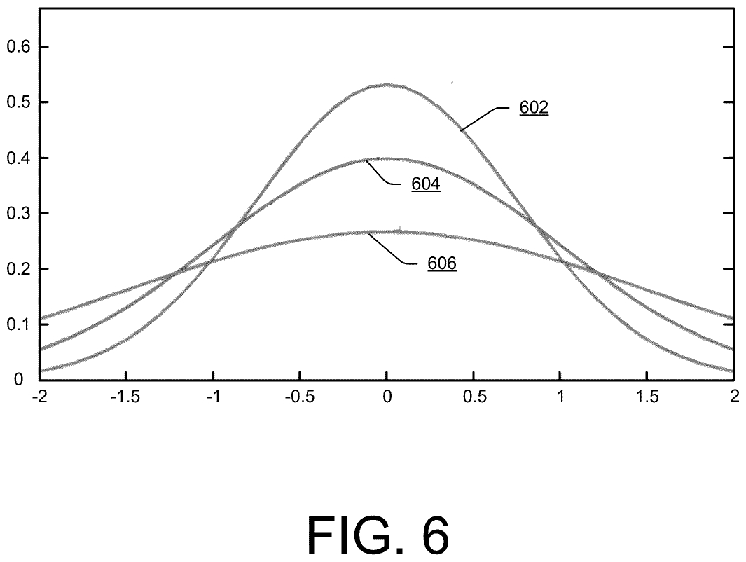

FIG. 6 illustrates three kurtosis graphs, graph 602 having zero kurtosis, graph 604 having a positive kurtosis, and a graph 606 having a negative kurtosis. Kurtosis of a waveform/distribution is a measure of whether the shape of the waveform (i.e., data) is heavy-tailed or light-tailed relative to a normal distribution. In a standard curve, the kurtosis of the curve describes the number of extremes that occur at the edges of the distribution. There are three types of kurtosis: mesokurtic with moderate width and peak (graph 602), leptokurtic having a positive kurtosis with more values in the tails and close to the mean (graph 604), and platykurtic having a negative kurtosis with fewer values in the tails and close to the mean (graph 606). Steeper curves, such as the 60 Hz voltage waveforms, have a positive kurtosis value (leptokurtic), and flatter curves have a negative kurtosis value (platykurtic).

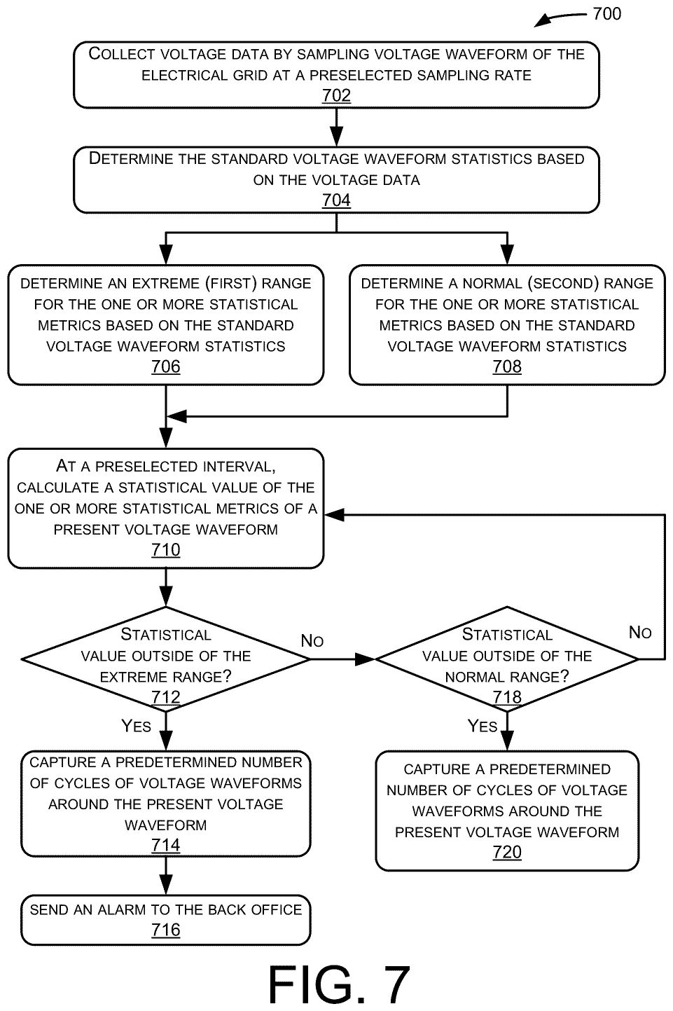

FIG. 7 illustrates an example process 700 for detecting a voltage anomaly in the electrical grid 100. To benchmark the statistical metrics, such as the crest factor, skewness, and kurtosis, of the waveform and to determine their range, data during normal grid operations are collected. While a plurality of electricity meters 116 may be utilized, the process 700 may also be interchangeably described from the perspective of a single electricity meter 116. At block 702, a plurality of electricity meters, such as the electricity meters 116, may collect voltage data for a predetermined time period, or until a predetermined number of samples is collected. For example, one hundred thousand (100k) residential electricity meters 116 on a common grid, such as the electrical grid 100, may collect the voltage data by sampling voltage waveforms on the individual lines 112 for two months. As described above with regard to FIG. 2, the electricity meter 116, more specifically, the metrology module 206 of the electricity meter 116, is capable of sampling the voltage information as a high sampling rate of 4-32 kHz. The electricity meter 116 may only select voltage waveforms sampled while the electrical grid 100 is known to be operating normally to determine standard voltage waveform statistics. In other words, the electricity meter 116 may collect voltage data continuously, however, the electricity meter 116 selects data of the voltage data corresponding to periods during which the electrical grid 100 is known to be operating normally.

At block 704, the electricity meter 116 may determine the standard voltage waveform statistics of the voltage by calculating the statistical metrics based on the voltage data, and store the standard voltage waveform statistics. Alternatively, the sampled voltage data may be transmitted from the electricity meter 116 to the back office 216 via the communication module 214, and the back office 216 may calculate the statistical metrics, store the voltage information, and communicate the statistical metrics back to the electricity meter 116. At block 706, the electricity meter 116 may determine a first range for the one or more statistical metrics based on the standard voltage waveform statistics. For example, the first range may be an extreme range covering +/−2σ, two standard deviations, from the mean of the crest factor, skewness, and kurtosis statistics. Additionally, after block 704, the electricity meter 116 may determine a second range, which may be a normal range for the one or more statistical metrics based on the standard voltage waveform statistics at block 708. For example, the normal range may be +/−σ, one standard deviation, from the mean of the crest factor, skewness, and kurtosis statistics.

After the benchmark, the standard voltage waveform statistics with the defined extreme range, is set at block 706, the electricity meter 116 may, at a preselected interval, calculate a statistical value of the one or more statistical metrics of a present voltage waveform sampled at block 710. For example, the electricity meter 116 may calculate the crest factor, skewness, and/or kurtosis of the present voltage waveform, which is being sampled at the preselected sampling rate, for a preselected interval of the present voltage waveform, such as each half cycle. However, the preselected interval may be varied or adjusted based on operating conditions, different underlying conditions observed, and/or to determine whether there are different underlying conditions to be observed. The electricity meter 116 may additionally calculate a linear combination of statistical values and/or non-linear time varying functions of the one or more statistical metrics as the statistical value(s). At block 712, the electricity meter 116 may determine whether the statistical value is outside of the extreme range. Determining whether the statistical value is outside of the extreme range may include determining whether one or more statistical values are outside of corresponding extreme ranges. In response to determining that the statistical value is outside of the extreme range at block 712, the electricity meter 116 may capture a predetermined number of cycles of voltage waveforms around the present voltage waveform at block 714. For example, the electricity meter 116 may capture six cycles around the present half cycle which is determined to have the statistical value outside of the extreme range. The predetermined number of cycles may also be varied or adjusted based on operating conditions, different underlying conditions observed, and/or to determine whether there are different underlying conditions to be observed. At block 716, the electricity meter 116 may, via the communication module 214, send an alarm to the back office 216 associated with the electrical grid 100.

In response to determining that the statistical value is not outside of the extreme range at 712, the electricity meter 116 may determine whether the statistical value is outside of the normal range at block 718. The electricity meter 116 may, in response to determining that the statistical value is outside of the normal range at block 718, capture the predetermined number of cycles of voltage waveforms around the present voltage waveform at block 720. In response to determining that the statistical value is not outside of the normal range at block 718, the process may loop back to block 710.

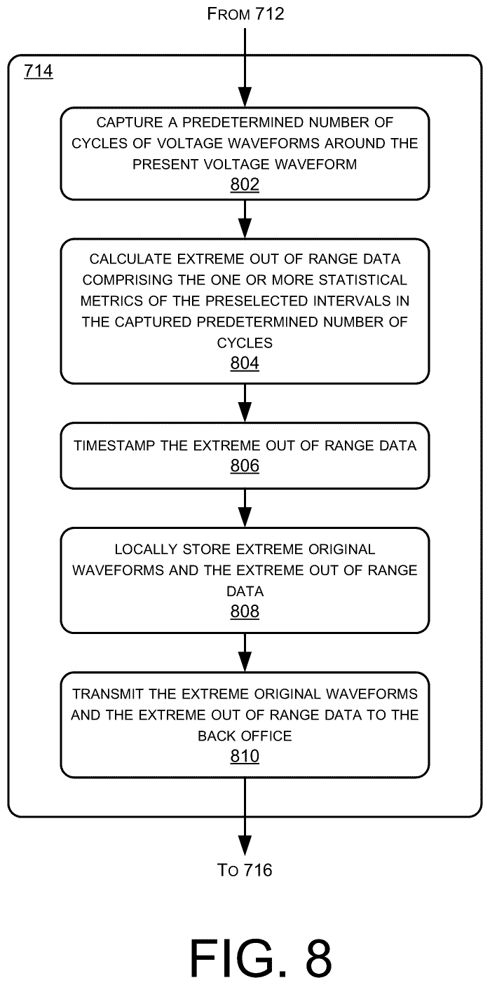

FIG. 8 illustrates a flow chart representing an example detail process of block 714 of FIG. 7. In response to determining that the statistical value is outside of the extreme range at block 712, the electricity meter 116 may capture a predetermined number of cycles of voltage waveforms around the present voltage waveform at block 714. For example, the electricity meter 116 may capture six cycles around the present half cycle which is determined to have the statistical value outside of the extreme range at block 802. The electricity meter 116 may calculate extreme out of range data comprising the one or more statistical metrics of the preselected intervals in the captured predetermined number of cycles of voltage waveforms at block 804. At block 806, the electricity meter 116 may timestamp the extreme out of range data, and locally store extreme original waveforms and the extreme out of range data, for example, into the memory 204, at block 808, where the extreme original waveforms include the captured predetermined number of cycles of voltage waveforms. At block 810, the electricity meter 116 may transmit, via the communication module 214, the extreme original waveforms and the extreme out of range data to the back office 216. As described above with reference to FIG. 2, the electricity meter 116, with the DI module 220 and DI agents running, may function as an edge device 116, and locally process the collected data. By transmitting only the extreme original waveforms and the extreme out of range data to the back office 216 after locally processing the data as described above, the electricity meter 116 effectively filters the collected and calculated data to relevant, i.e., abnormal, data, thus reducing the amount of data being transmitted to the back office 216. The back office 216 may store the extreme original waveforms and the extreme out of range data at the back office 216 or in a cloud storage.

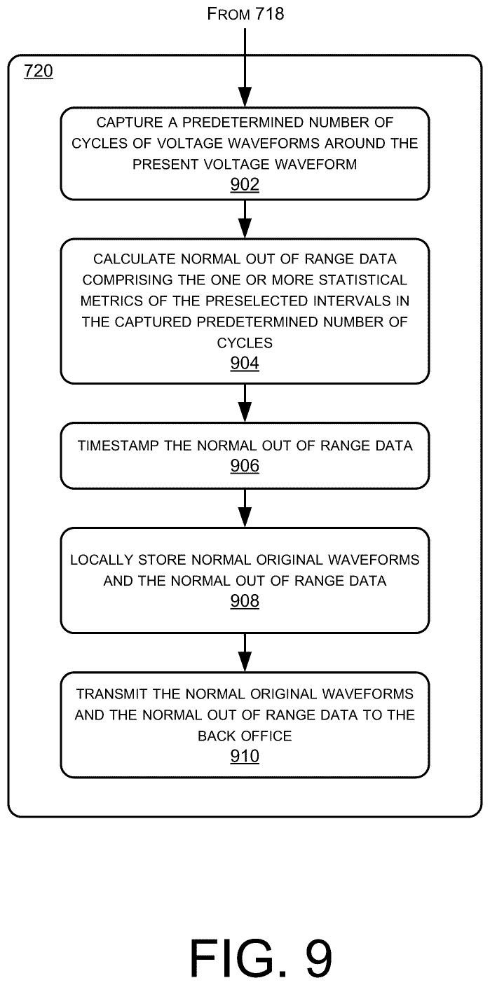

FIG. 9 illustrates a flow chart representing an example detail process of block 720 of FIG. 7. In response to determining that the statistical value is outside of the normal range at block 718, the electricity meter 116 may capture the predetermined number of cycles of voltage waveforms around the present voltage waveform at block 902. For example, the electricity meter 116 may capture six cycles around the present half cycle which is determined to have the statistical value outside of the normal range at block 718. The electricity meter 116 may calculate normal out of range data comprising the one or more statistical metrics of the preselected intervals in the captured predetermined number of cycles of voltage waveforms at block 904. At block 906, the electricity meter 116 may timestamp the normal out of range data, and locally store normal original waveforms and the normal out of range data, for example, into the memory 204, at block 908, where the normal original waveforms include the captured predetermined number of cycles of voltage waveforms. At block 910, the electricity meter 116 may transmit, via the communication module 214, the normal original waveforms and the normal out of range data to the back office 216. The electricity meter 116 may transmit the normal original waveforms and the normal out of range data to the back office 216 periodically at a predetermined interval, such as once a day, or in response to receiving a meter interrogation from the back office 216. The back office 216 may store the normal original waveforms and the normal out of range data at the back office 216 or in a cloud storage.

Some or all operations of the methods, or processes, described above can be performed by execution of computer-readable instructions stored on a computer-readable storage medium, as defined below. The terms “computer-readable medium,” “computer-readable instructions,” and “computer executable instruction” as used in the description and claims, include routines, applications, application modules, program modules, programs, components, data structures, algorithms, and the like. Computer-readable and -executable instructions can be implemented on various system configurations, including single-processor or multiprocessor systems, minicomputers, mainframe computers, personal computers, hand-held computing devices, microprocessor-based, programmable consumer electronics, combinations thereof, and the like.

The computer-readable storage media may include volatile memory (such as random-access memory (RAM)) and/or non-volatile memory (such as read-only memory (ROM), flash memory, etc.). The computer-readable storage media may also include additional removable storage and/or non-removable storage including, but not limited to, flash memory, magnetic storage, optical storage, and/or tape storage that may provide non-volatile storage of computer-readable instructions, data structures, program modules, and the like.

A non-transitory computer-readable storage medium is an example of computer-readable media. Computer-readable media includes at least two types of computer-readable media, namely computer-readable storage media and communications media. Computer-readable storage media includes volatile and non-volatile, removable and non-removable media implemented in any process or technology for storage of information such as computer-readable instructions, data structures, program modules, or other data. Computer-readable storage media includes, but is not limited to, phase change memory (PRAM), static random-access memory (SRAM), dynamic random-access memory (DRAM), other types of random-access memory (RAM), read-only memory (ROM), electrically erasable programmable read-only memory (EEPROM), flash memory or other memory technology, compact disk read-only memory (CD-ROM), digital versatile disks (DVD) or other optical storage, magnetic cassettes, magnetic tape, magnetic disk storage or other magnetic storage devices, or any other non-transmission medium that can be used to store information for access by a computing device. In contrast, communication media may embody computer-readable instructions, data structures, program modules, or other data in a modulated data signal, such as a carrier wave, or other transmission mechanism. As defined herein, computer-readable storage media do not include communication media.

The computer-readable instructions stored on one or more non-transitory computer-readable storage media, when executed by one or more processors, may perform operations described above with reference to FIGS. 2-9. Generally, computer-readable instructions include routines, programs, objects, components, data structures, and the like that perform particular functions or implement particular abstract data types. The order in which the operations are described is not intended to be construed as a limitation, and any number of the described operations can be combined in any order and/or in parallel to implement the processes.

### CONCLUSION

Although the subject matter has been described in language specific to structural features and/or methodological acts, it is to be understood that the subject matter defined in the appended claims is not necessarily limited to the specific features or acts described. Rather, the specific features and acts are disclosed as exemplary forms of implementing the claims.

What is claimed is:

1. A method for detecting voltage anomaly in an electrical grid, the method comprising:
collecting voltage data by sampling a voltage waveform of the electrical grid at a preselected sampling rate;
determining standard voltage waveform statistics of voltage of the electrical grid based on the voltage data, the standard voltage waveform statistics including one or more statistical metrics;
determining a range for the one or more statistical metrics based on the standard voltage waveform statistics;
at a preselected interval, calculating a statistical value of the one or more statistical metrics of a present voltage waveform sampled at the preselected sampling rate;
determining whether the statistical value is outside of the range;
in response to determining that the statistical value is outside of the range:
capturing a predetermined number of cycles of voltage waveforms around the present voltage waveform; and
sending an alarm to a remote computing device associated with the electrical grid.

2. The method of claim 1, wherein determining the standard voltage waveform statistics of the voltage of the electrical grid based on the voltage data includes:
selecting data of the voltage data corresponding to periods during which the electrical grid is known to be operating normally; and
determining the standard voltage waveform statistics of the voltage of the electrical grid based on the selected data.

3. The method of claim 1, wherein the one or more statistical metrics include at least one of:
a crest factor;
kurtosis; or
skewness.

4. The method of claim 1, wherein capturing the predetermined number of cycles of voltage waveforms around the present voltage waveform includes:
calculating out of range data comprising the one or more statistical metrics of the preselected intervals in the captured predetermined number of cycles of voltage waveforms;
timestamping the out of range data;
locally storing original waveforms and the out of range data, the original waveforms comprising the captured predetermined number of cycles of voltage waveforms; and
transmitting the original waveforms and the out of range data to the remote computing device.

5. The method of claim 1, wherein the range is a first range, the method further comprising:
determining a second range for the one or more statistical metrics based on the standard voltage waveform statistics;
determining whether the statistical value is outside of the second range; and
in response to determining that the statistical value is outside of the second range, capturing the predetermined number of cycles of voltage waveforms around the present voltage waveform.

6. The method of claim 5, wherein in response to determining that the statistical value is outside of the second range and within the first range, capturing the predetermined number of cycles of voltage waveforms around the present voltage waveform includes:
calculating out of range data comprising the one or more statistical metrics of the preselected intervals in the captured predetermined number of cycles of voltage waveforms;
timestamping the out of range data;
locally storing original waveforms and the out of range data, the original waveforms comprising the captured predetermined number of cycles of voltage waveforms; and
transmitting the original waveforms and the out of range data to the remote computing device.

7. The method of claim 6, wherein transmitting the original waveforms and the out of range data to the remote computing device includes:
transmitting the original waveforms and the out of range data to the remote computing device periodically at a predetermined interval.

8. An electricity meter comprising:
one or more processors;
one or more modules coupled to the one or more processors, the one or more modules including a communication module and a metrology module; and
memory coupled to the one or more processors, the memory storing thereon computer-executable instructions that, when executed by the one or more processors, cause the one or more processors to perform operations utilizing the one or more modules, the operations comprising:
collecting voltage data by sampling a voltage waveform of an electrical grid at a preselected sampling rate;
determining standard voltage waveform statistics of voltage of the electrical grid based on the voltage data, the standard voltage waveform statistics including one or more statistical metrics;
determining a range for the one or more statistical metrics based on the standard voltage waveform statistics;
at a preselected interval, calculating a statistical value of the one or more statistical metrics of a present voltage waveform sampled at the preselected sampling rate;
determining whether the statistical value is outside of the range;
in response to determining that the statistical value is outside of the range:
capturing a predetermined number of cycles of voltage waveforms around the present voltage waveform; and
sending an alarm to a remote computing device associated with the electrical grid.

9. The electricity meter of claim 8, wherein determining the standard voltage waveform statistics of the voltage of the electrical grid based on the voltage data includes:
selecting data of the voltage data corresponding to periods during which the electrical grid is known to be operating normally; and
determining the standard voltage waveform statistics of the voltage of the electrical grid based on the selected data.

10. The electricity meter of claim 8, wherein the one or more statistical metrics include at least one of:
a crest factor;
kurtosis; or
skewness.

11. The electricity meter of claim 8, wherein capturing the predetermined number of cycles of voltage waveforms around the present voltage waveform includes:
calculating out of range data comprising the one or more statistical metrics of the preselected intervals in the captured predetermined number of cycles of voltage waveforms;
timestamping the out of range data;
locally storing original waveforms and the out of range data, the original waveforms comprising the captured predetermined number of cycles of voltage waveforms; and
transmitting the original waveforms and the out of range data to the remote computing device.

12. The electricity meter of claim 8, wherein the range is a first range, the operations further comprising:
determining a second range for the one or more statistical metrics based on the standard voltage waveform statistics;
determining whether the statistical value is outside of the second range; and
in response to determining that the statistical value is outside of the second range, capturing the predetermined number of cycles of voltage waveforms around the present voltage waveform.

13. The electricity meter of claim 12, wherein in response to determining that the statistical value is outside of the second range and within the first range, capturing the predetermined number of cycles of voltage waveforms around the present voltage waveform includes:
calculating out of range data comprising the one or more statistical metrics of the preselected intervals in the captured predetermined number of cycles of voltage waveforms;
timestamping the out of range data;
locally storing original waveforms and the out of range data, the original waveforms comprising the captured predetermined number of cycles of voltage waveforms; and
transmitting the original waveforms and the out of range data to the remote computing device.

14. The electricity meter of claim 13, wherein transmitting the original waveforms and the out of range data to the remote computing device includes:
transmitting the original waveforms and the out of range data to the remote computing device periodically at a predetermined interval.

15. A non-transitory computer-readable storage medium storing thereon computer executable instructions that, when executed by one or more processors of an electricity meter, cause the one or more processors to perform operations comprising:
collecting voltage data by sampling a voltage waveform of an electrical grid at a preselected sampling rate;
determining standard voltage waveform statistics of voltage of the electrical grid based on the voltage data, the standard voltage waveform statistics including one or more statistical metrics;
determining a range for the one or more statistical metrics based on the standard voltage waveform statistics;
at a preselected interval, calculating a statistical value of the one or more statistical metrics of a present voltage waveform sampled at the preselected sampling rate;
determining whether the statistical value is outside of the range;
in response to determining that the statistical value is outside of the range:
capturing a predetermined number of cycles of voltage waveforms around the present voltage waveform; and
sending an alarm to a remote computing device associated with the electrical grid.

16. The non-transitory computer-readable storage medium of claim 15, wherein determining the standard voltage waveform statistics of the voltage of the electrical grid based on the voltage data includes:
selecting data of the voltage data corresponding to periods during which the electrical grid is known to be operating normally; and
determining the standard voltage waveform statistics of the voltage of the electrical grid based on the selected data.

17. The non-transitory computer-readable storage medium of claim 15, wherein the one or more statistical metrics include at least one of:
a crest factor;
kurtosis; or
skewness.

18. The non-transitory computer-readable storage medium of claim 15, wherein capturing the predetermined number of cycles of voltage waveforms around the present voltage waveform includes:
calculating out of range data comprising the one or more statistical metrics of the preselected intervals in the captured predetermined number of cycles of voltage waveforms;
timestamping the out of range data;
locally storing original waveforms and the out of range data, the original waveforms comprising the captured predetermined number of cycles of voltage waveforms; and
transmitting the original waveforms and the out of range data to the remote computing device.

19. The non-transitory computer-readable storage medium of claim 15, wherein the range is a first range, the operations further comprising:
determining a second range for the one or more statistical metrics based on the standard voltage waveform statistics;
determining whether the statistical value is outside of the second range; and
in response to determining that the statistical value is outside of the second range, capturing the predetermined number of cycles of voltage waveforms around the present voltage waveform.

20. The non-transitory computer-readable storage medium of claim 19, wherein in response to determining that the statistical value is outside of the second range and within the first range, capturing the predetermined number of cycles of voltage waveforms around the present voltage waveform includes:
calculating out of range data comprising the one or more statistical metrics of the preselected intervals in the captured predetermined number of cycles of voltage waveforms;
timestamping the out of range data;
locally storing original waveforms and the out of range data, the original waveforms comprising the captured predetermined number of cycles of voltage waveforms; and
transmitting the original waveforms and the out of range data to the remote computing device periodically at a predetermined interval.

21. A method performed by an edge device of an electrical grid for detecting voltage anomaly in the electrical grid, the method comprising:
collecting voltage data by sampling a voltage waveform of the electrical grid at a preselected sampling rate;
determining standard voltage waveform statistics of voltage of the electrical grid based on the voltage data, the standard voltage waveform statistics including one or more statistical metrics by:
selecting data of the voltage data corresponding to periods during which the electrical grid is known to be operating normally; and
determining the standard voltage waveform statistics of the voltage of the electrical grid based on the selected data, and
determining a range for the one or more statistical metrics based on the standard voltage waveform statistics;
at a preselected interval, calculating a statistical value of the one or more statistical metrics of a present voltage waveform sampled at the preselected sampling rate;
determining whether the statistical value is outside of the range;
in response to determining that the statistical value is outside of the range:
capturing a predetermined number of cycles of voltage waveforms around the present voltage waveform; and
sending an alarm to a remote computing device associated with the electrical grid.

22. The method of claim 21, wherein capturing the predetermined number of cycles of voltage waveforms around the present voltage waveform includes:
calculating out of range data comprising the one or more statistical metrics of the preselected intervals in the captured predetermined number of cycles of voltage waveforms;
timestamping the out of range data;
locally storing original waveforms and the out of range data, the original waveforms comprising the captured predetermined number of cycles of voltage waveforms; and
transmitting the original waveforms and the out of range data to the remote computing device.

23. The method of claim 21, wherein the range is a first range, the method further comprising:
determining a second range for the one or more statistical metrics based on the standard voltage waveform statistics;
determining whether the statistical value is outside of the second range; and
in response to determining that the statistical value is outside of the second range, capturing the predetermined number of cycles of voltage waveforms around the present voltage waveform.

24. The method of claim 23, wherein in response to determining that the statistical value is outside of the second range and within the first range, capturing the predetermined number of cycles of voltage waveforms around the present voltage waveform includes:
calculating out of range data comprising the one or more statistical metrics of the preselected intervals in the captured predetermined number of cycles of voltage waveforms;
timestamping the out of range data;
locally storing original waveforms and the out of range data, the original waveforms comprising the captured predetermined number of cycles of voltage waveforms; and
transmitting the original waveforms and the out of range data to the remote computing device.

25. The method of claim 21, wherein the method is performed by a distributed intelligence module of the edge device.
